(19) United States
(12) Patent Application Publication
(10) Pub. No.: US 2025/0112017 A1
(43) Pub. Date: Apr. 3, 2025

(54) IMAGING THOUSANDS OF ELECTRON BEAMS DURING WORKPIECE INSPECTION

(71) Applicant: KLA Corporation, Milpitas, CA (US)

(72) Inventors: Xinrong Jiang, Palo Alto, CA (US); Youfei Jiang, Milpitas, CA (US); Luca Grella, Gilroy, CA (US)

(21) Appl. No.: 18/375,512

(22) Filed: Sep. 30, 2023

(51) Int. Cl. H01J 37/12; H01J 37/05; H01J 37/073; H01J 37/147; H01J 37/285

(52) U.S. Cl. CPC H01J 37/12; H01J 37/05; H01J 37/073; H01J 37/1474; H01J 37/285; H01J 2237/04924; H01J 2237/1207

(57) ABSTRACT

Beamlets are generated from the electron beam using an aperture array downstream of the single global collimated lens. The beamlets are directed through an image lens array in a path of the beamlets downstream of the aperture array that individually focuses the beamlets onto the intermediate image plane with the image lens array. The beamlets are then directed at a workpiece on a stage using a transfer lens array downstream of the image lens array. A path of the beamlets does not include a crossover.

### FIELD OF THE DISCLOSURE

This disclosure relates to workpiece inspection and, more particularly, to inspection of semiconductor wafers.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer or other workpiece using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

To examine semiconductor defects, electron beam inspections (EBIs) previously used a single electron beam or multiple electron beams with a crossover. With a single electron beam, the semiconductor defects on a fabricated workpiece were examined within an integrated circuit die and the defects are found by comparing the inspecting signals with the standard signals without defects. The size of an integrated circuit die may be varied in La x La from, for example, 1×1 mm² to 100×100 mm² (i.e., La is from 1 mm to 100 mm). For simplicity, FIG. 1 shows a smallest die with L_{d}=1 mm (i.e., 1000 microns). To scan a region within which the electron beam deflection blurs are acceptable, an integrated circuit die is divided into many main fields of view (MFOV or MF), such as the MF=L_{MF}×L_{MF}=100×100 square microns in FIG. 1.

A single electron beam with a pixel size of P in FIG. 1 may scan over the first main field of view (e.g., x is from −500 to −400 microns and y is from 400 to 500 microns) to inspect for integrated circuit defects. After the first main field of view scan is finished, the single electron beam with a pixel size of P may move to the second main field of view (e.g., x is from −400 to −300 microns and y is from 400 to 500 microns) and scan over the second main field of view. Repeatedly the single electron beam with a pixel size of P may move to the last main field of view for the die in FIG. 1 (e.g., x is from 400 to 500 microns and y is from −500 to −400 microns) and scan over the last main field of view to inspect the defects. In a conventional method of step-and-scan, it can be practical to move the stage that holds a workpiece being inspected from one main field of view to another as shown in FIG. 1.

Within a main field of view (e.g., L_{MF}×L_{MF}=100×100 square microns), the single electron beam with a pixel size of P may perform a raster scan from PA to PB, as shown in FIG. 2. The throughput of an electron beam inspection (EBI) tool is evaluated with the total time used to examine a complete die (L_{d}×L_{d}). The total time includes time for three types of operations. The first time is the total pixel time, Tₚᵢₓ, given by Equation 1.

$${T}_{pix} = \frac{1}{f} * {( \frac{{L}_{d}}{P} )}^{2} \qquad ( 1 )$$

In Equation 1, f is the raster scan frequency (i.e., the scan speed). 1/f is considered as the dwell time of a pixel for the image quality with sufficient signal-to-noise ratio. The second time is total retrace time, Tᵣₜᵣ, in which the electron beam moves back from right to left in the dash-line direction in all main fields. The total retrace time is given by Equation 2.

$${T}_{rtr} = {t}_{rtr} * \frac{{L}_{d}^{2}}{{PL}_{MF}} \qquad ( 2 )$$

In Equation 2, tᵣₜᵣ is a single retrace time, which typically is approximately 1 micro second. The third time is total stage motion time, T_{stg}, given by Equation 3.

$${T}_{stg} = {t}_{stg} {( \frac{{L}_{d}}{{L}_{MF}} )}^{2} \qquad ( 3 )$$

In Equation 3, t_{stg} is a single time of the stage motion from one main field to another, which typically is approximately 0.4 seconds.

The previous method of imaging with multiple electron beams directed at a workpiece inevitably introduces a beam crossover, as is shown in FIG. 3. Assume that the multiple electron beams (e.g., hundreds of electron beamlets) are created with a micro lens array (MLA) in the upper column from the electron emission source to the intermediate image plane (IIP) in FIG. 3. Two global lenses, the global transfer lens (GTL) and global objective lens (GOL), focus the multiple electron beams from the IIP onto a wafer (WF) in a de-magnified projection optics. A beam crossover (xo) is formed and located around the focal plane of the global objective lens for telecentric image-formation at the wafer. Two global deflectors (the pre-scanner GD1 and main-scanner GD2) are used to simultaneously scan all the electron beams over the wafer. The Wien filter (Wien) is used to split secondary electron beams (SEB) from the primary electron beams. The secondary electron beams are deflected by the Wien filter toward the detector array (DA).

Both a single electron beam and multiple electron beams have disadvantages.

Using a single electron beam for wafer inspection has low throughput. Consider an electron beam inspection for a small integrated circuit die L_{d}=5 mm and assume that the typical EBI conditions are a pixel size P=15 nm, scan frequency f=400 MHz, main field size L_{MF}=100 microns, single retrace time tᵣₜᵣ=1 micro second, and single stage motion time t_{stg}=0.4 seconds. Substituting these conditions into the Equations 1-3 provides a total pixel time Tₚᵢₓ=4.6 minutes, total retrace time Tᵣₜᵣ=0.28 minutes, and total stage motion time T_{stg}=16.7 minutes. The total time (throughput) is Tₚᵢₓ+Tᵣₜᵣ+T_{stg}=21.6 minutes, in which the stage motion time is 77% of the total time.

Using a multiple electron beam array to inspect the same die of L_{d}=5 mm, the total stage motion time and the total pixel time can be reduced. Assume that the multiple electron beam array is 50×50 (i.e., 2500) beams with a pixel size of P (15 nm). Then assume that the pitch between the beams is 100 microns (referring to FIG. 1) and that each beam scans over a main field of L_{MF}=100 microns. Without the stage motion, the total inspection time with these conditions in a main field would be Tₚᵢₓ+Tᵣₜᵣ=0.11+0.007=0.117 seconds, being more than 11000x higher throughput than the EBI with a single electron beam.

However, there is degraded optical resolutions by Coulomb interactions around the beam crossover. All beamlets (i.e., all beam currents) need to be proximate and pass through the beam crossover (xo) in the in FIG. 3, so the Coulomb interactions between electrons around the crossover become dominant, degrading each individual resolution of beamlets at the wafer. Computer simulations found that each beamlet resolution is limited by the total beam current of all beamlets in a relation of d˜I^{2/3}, in which dis the optical blur induced by the Coulomb interactions and I is the total beam current. Accordingly, the beam crossover in the projection optics of FIG. 3 may either strongly limit the beamlet number (given a constant beamlet current) or each beamlet current (given a constant beamlet number).

Therefore, improved systems and techniques are needed.

### BRIEF SUMMARY OF THE DISCLOSURE

A system is provided in a first embodiment. The system includes an electron source that emits an electron beam and a stage configured to hold a workpiece. A single global magnetic lens is in a path of the electron beam. A global beam-limiting aperture is in the path of the electron beam downstream of the single global magnetic lens. A single global collimated lens is in the path of the electron beam downstream of the global beam-limiting aperture. The single global collimated lens is configured to focus the electron beam. An aperture array is in the path of the electron beam downstream of the single global collimated lens. The aperture array is configured to generate a plurality of beamlets from the electron beam. The aperture array is illuminated telecentrically by the electron beam. The plurality of beamlets includes at least 1000 beamlets. An image lens array is in a path of the beamlets downstream of the aperture array. The beamlets are individually focused by the image lens array onto the intermediate image plane. A transfer lens array is in the path of the beamlets downstream of the image lens array. The beamlets are directed at the workpiece on the stage using the transfer lens array. The path of the beamlets does not include a crossover.

The beamlets can include at least 2500 beamlets.

The beamlets can be configured to illuminate a single die on the workpiece.

The image lens array can include three electrode plates. Each of the electrode plates includes a plurality of apertures. One of the electrode plates can be biased such that the beamlets are focused. Another two of the electrode plates can be grounded.

The system can further include a Wien filter disposed in the path of the beamlets between the transfer lens array and the stage and a detector array configured to measure the secondary electrons. The Wien filter is configured to split secondary electrons from primary electrons. A relationship between an angle of the beamlets relative to the workpiece and an angle caused by deflection using the Wien filter may be such that source energy dispersion blurs generated by the electrostatic and magnetic deflection fields in the Wien filter are cancelled. The detector array and a global projection lens in a path of the second electrons can be configured to be mechanically adjusted along the optical axis.

Spacing of apertures in the image lens array and transfer lens array may be from 10 um to 1 mm.

The system can further include a pre-scanner and a main scanner in the path of the beamlets. The pre-scanner and the main-scanner are configured to scan the beamlets simultaneously.

The electron source can be a thermal field emission source. The thermal field emission source may be the only source for the electron beam.

The electron source can include a transparent substrate in the path of the beamlets and a plurality of laser beams that illuminate the patterned thin film. The transparent substrate has a patterned thin film.

The system can further include an objective lens array that defines a gap distance between electrodes in the objective lens array configured to optimize image resolutions of primary electron beamlets and collection efficiencies of secondary electron beamlets.

The system can further include an objective lens array disposed less than 100 μm along the optical path of the beamlets from a surface of the workpiece.

A method is provided in a second embodiment. The method includes emitting an electron beam with an electron source. The electron beam is directed through a single global magnetic lens. The electron beam is directed through a global beam-limiting aperture downstream of the single global magnetic lens. The electron beam is directed through a single global collimated lens in the path of the electron beam downstream of the global beam-limiting aperture whereby the electron beam is focused by the single global collimated lens. A plurality of beamlets is generated from the electron beam using an aperture array downstream of the single global collimated lens.

The plurality of beamlets includes at least 1000 beamlets. The aperture array is illuminated telecentrically by the electron beam. The beamlets are directed through an image lens array in a path of the beamlets downstream of the aperture array thereby individually focusing the beamlets onto the intermediate image plane with the image lens array. The beamlets are directed at a workpiece on a stage using a transfer lens array downstream of the image lens array. A path of the beamlets does not include a crossover.

The beamlets can include at least 2500 beamlets.

The beamlets can illuminate a single die on the workpiece.

The method can further include splitting secondary electrons from primary electrons between the transfer lens and the stage using a Wien filter and measuring the secondary electrons. In an instance, the method includes cancelling energy dispersion blurs generated by the electrostatic and magnetic deflection fields in the Wien filter using a relationship between an angle of the beamlets relative to the workpiece and an angle caused by deflection using the Wien filter. In an instance, the method includes correcting transfer chromatic blur induced by the Wien filter due to source energy spread by cancelling the source energy spread. In an instance, the method includes adjusting a position of a detector array and a global projection lens along an optical axis of the secondary electrons.

The method can include simultaneously scanning the beamlets with a pre-scanner and a main scanner.

Each of the beamlets can be formed and imaged separately using an image lens array, a transfer lens array and an objective lens array.

A same focusing voltage can be applied to an image lens array, a transfer lens array, and an objective lens array that the beamlets pass through.

The method can further include image-formation of secondary electron beamlets from a secondary electron image plane to a detector array through a projection optics. The projection optics includes two global project lenses thereby cancelling secondary electron beamlet rotation, coma, distortion, and transfer chromatic aberration.

The method can further include creating the at least 1000 beamlets modulated by a laser using patterned photocathode sourcelets on an image lens array, a transfer lens array, and an objective lens array.

### DESCRIPTION OF THE DRAWINGS

For a fuller understanding of the nature and objects of the disclosure, reference should be made to the following detailed description taken in conjunction with the accompanying drawings, in which:

FIG. 1 shows electron beam inspection over an integrated circuit (L_{d}×L_{d});

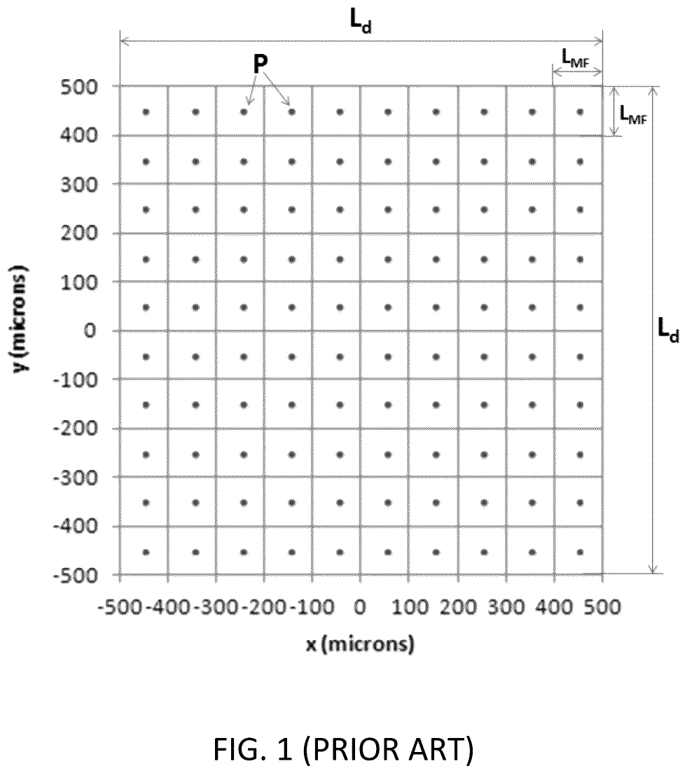

FIG. 2 shows a raster scan with a single electron beam within a main field (MF);

FIG. 3 shows imaging multi-electron beams on a workpiece with a crossover (xo);

FIG. 4 is a diagram of a multi-electron beam apparatus without crossovers in accordance with the present disclosure;

FIG. 5 shows a diagram of an image lens array (ILA) in accordance with the present disclosure, wherein (a) is a complete aperture array (AA) and ILA and (b) shows an enlarged view of a central area of the AA and ILA;

FIG. 6 is a cross-sectional view of (b) in FIG. 5, showing 50×50 holes of the electrode plates in an ILA;

FIG. 7(a) is a simulation of electron trajectories with 50×50 beamlets focused by an ILA and transfer lens array (TLA);

FIG. 7(b) is an enlarged view of the electron trajectories in FIG. 7(a);

FIG. 8(a) is a diagram of an objective lens array (OLA) and simulation of trajectories with 50×50 electron beamlets;

FIG. 8(b) is an enlarged view of FIG. 8(a) showing that 50×50 primary electron beamlets are focused (image-formed) at a workpiece simultaneously;

FIG. 9(a) is a ray-tracing simulation of 50×50 secondary electron beamlets emitted from a workpiece;

FIG. 9(b) is an enlarged view of the secondary electron trajectories in FIG. 9(a);

FIG. 9(c) shows secondary electron distributions in the image plane of the OLA (SE-IP) according to Monte Carlo simulations;

FIG. 10 is a diagram of a multi-electron beam apparatus with globally-tilted optics in accordance with the present disclosure for correcting energy dispersion blurs in a primary electron column and collecting image-signals at detector array in secondary electron column;

FIG. 11 shows an globally-tilted optical column for projecting secondary electron beamlets on a detector array (DA);

FIG. 12 is a view of a first quadrant detector array (DA) for collecting 50×50 SE beamlets;

FIG. 13 is Monte Carlo simulations, wherein (a), (b), (c), and (d) show the Monte Carlo simulations of SE collections by the sub-detectors Da, Db, Dc, and Da in FIG. 12, respectively;

FIG. 14 shows a method of creating electron emissions with a patterned photocathode;

FIG. 15 shows a multi-electron beam apparatus with patterned photocathode sourcelets in accordance with the present disclosure;

FIG. 16 shows a scheme for step-and-scan with a main field in a multi-electron beam apparatus; and

FIG. 17 is a flowchart of a method in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

A scanning electron beam inspection tool can be used to inspect semiconductor devices fabricated on a workpiece, such as a semiconductor wafer. Commercially-available electron beam-based inspection machines currently use a single electron beam column, based on the principle of scanning electron microscopy. Low throughputs are an obstacle in such machines because the images are acquired as described above pixel-by-pixel in a sequential manner. However, the scan field of view (FOV) of a single electron beam is only limited in tens of microns due to optical blurs and distortion and the motions of the stage holding the workpiece are largely required to inspect an integrated circuit die in millimeters to tens of millimeters. A large number of stage motions will lower the throughput. The low throughput with a single electron beam raises inspection costs and is undesirable.

To improve the throughput of workpiece inspections, multi-electron beam tools were developed. However, currently-developed multi-electron beam tools introduce a beam crossover near the objective lens, which degrades imaging resolutions due to strong Coulomb interactions between electrons around the beam crossover. Limiting the influence of Coulomb effects on resolutions limits the number of electron beamlets and reduces the beam current of each beamlet, which limits the tool throughput.

Embodiments disclosed herein resolve these drawbacks. Thousands of primary electron beams are created and image-formed on a wafer or other workpiece separately without a beam crossover near the objective lens. Furthermore, thousands of secondary electron beams are efficiently collected by a detector array without cross-talk. As a result, the throughput can be raised hundreds of times compared to a conventional machine with single electron beam inspections.

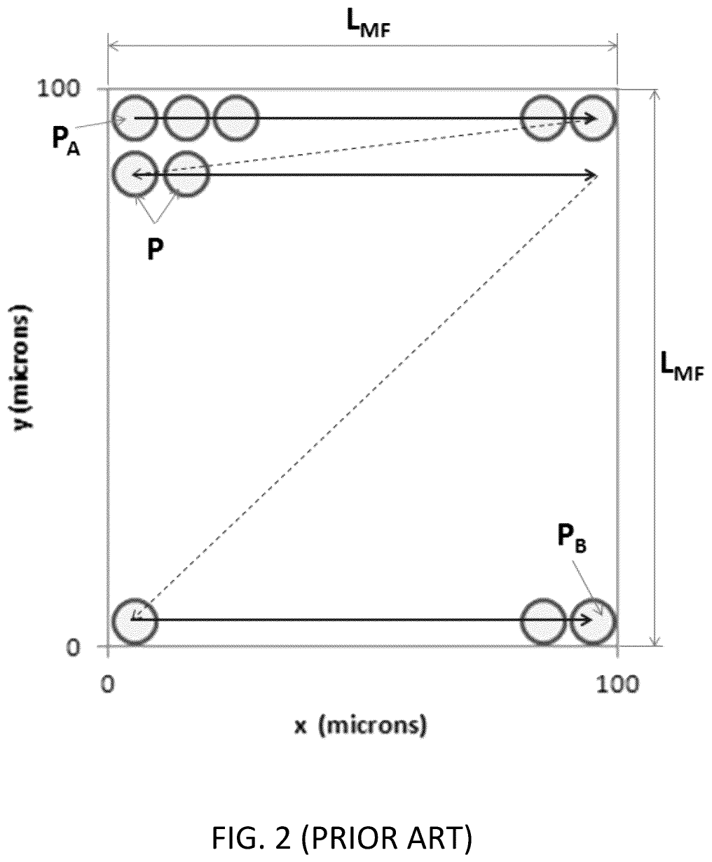

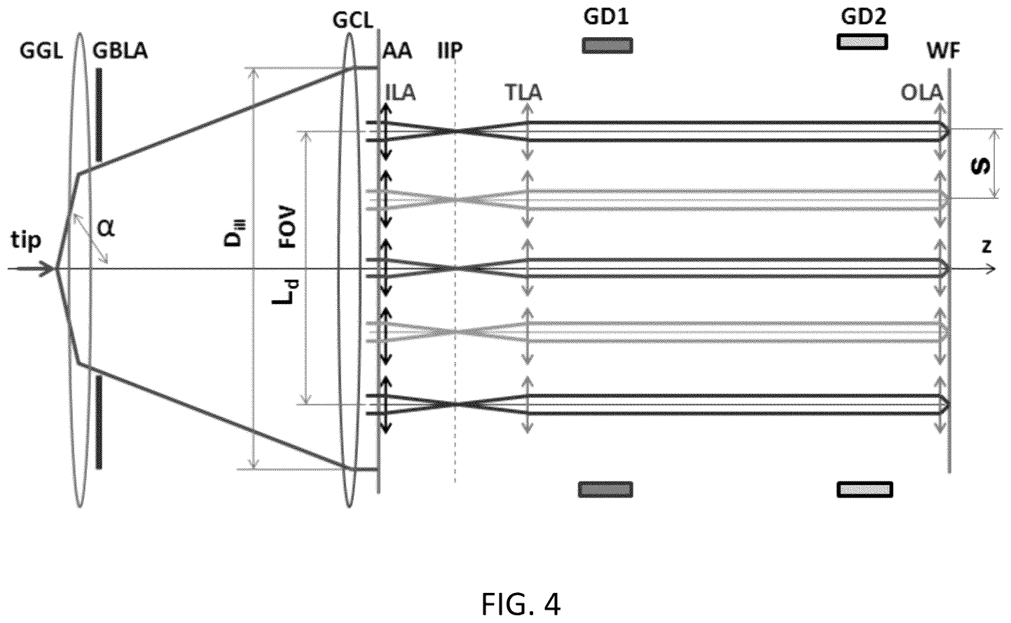

FIG. 4 is a diagram of a multi-electron beam apparatus without crossovers in which thousands of electron beams (keBs) are created and image-formed at a wafer or other workpiece without beam crossovers. A tip in a thermal field emitter (TFE) source (or another electron source) emits electrons used to form an electron beam. The electrons are focused by a global gun lens (GGL), such as a global magnetic lens. A global beam-limiting aperture (GBLA) can be used to select the total beam current. Given the brightness of the tip emission and GGL focusing strength, the total beam current is defined by the emission angle α. The higher the GGL focusing strength, the higher the total beam current will be. A global collimated lens (GCL) can be used to further focus the global electron beam so that it illuminates the aperture array (AA) telecentrically. The AA-selected telecentric beamlets are separately focused on the intermediate image plane (IIP) by the micro lenses in the image lens array (ILA). Each individual beamlet is independently image-formed from the IIP onto a workpiece (e.g., a wafer (WF)) by the micro lenses in the transfer lens array (TLA) and objective lens array (OLA). The pitch (spacing) between beamlets is s, and it may be designed as the size of a main field (i.e., s=L_{MF}). The beamlet distribution may be configured as the size of an integrated circuit die (La), as shown in FIG. 4. The global illumination beam diameter, Dᵢₗₗ may be greater than √2L_{d}. Two global deflectors, the pre-scanner (GD1) and main scanner (GD2), can be used to scan. For example, a raster scan can be performed like that in FIG. 2. The beamlets can be scanned over each corresponding main field of view (L_{MF}×L_{MF}) simultaneously.

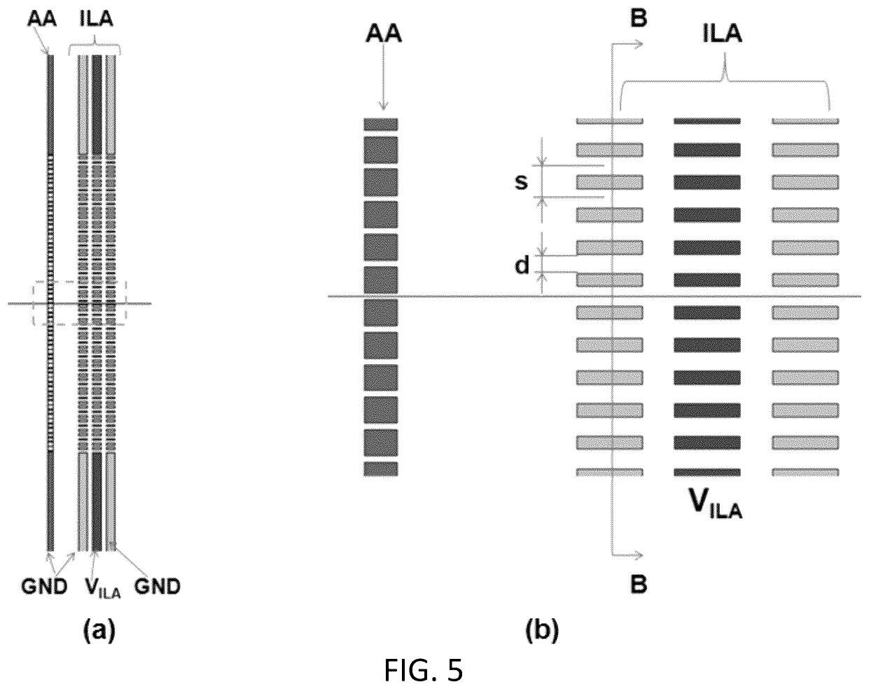

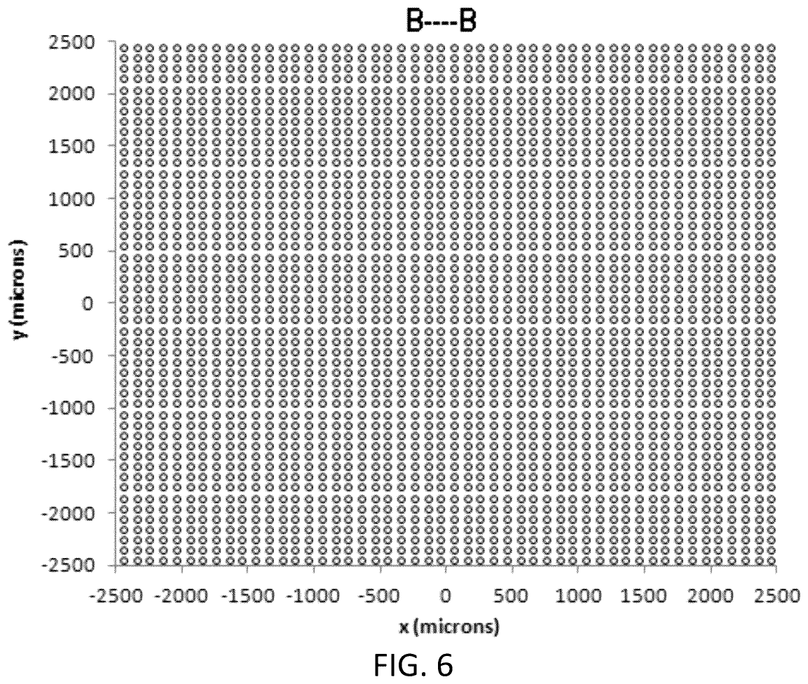

The image lens array (ILA) can include three pieces of electrode plates with N×N holes, as shown in FIGS. 5 and 6, where 50×50 micro image lenses are designed for the optics of 2500 beamlets. FIG. 5(a) shows a complete view of the aperture array (AA) and image lens array (ILA). The micro image lenses are electrostatic Einzel lenses. Applying a voltage V_{ILA} to the middle electrode can focus the beamlets. The other electrodes, including the AA plate, can be grounded. FIG. 5(b) is an enlarged view of the central area in FIG. 5(a), showing the size of holes is d in the tens of microns and the spacing (pitch) between holes is s in the tens of microns to sub-millimeters. The gap between the electrodes in an ILA can be tens of microns. FIG. 6 is the cross-section view of FIG. 5(b), showing 50×50 holes in each electrode plate. The spacing between holes is s=100 microns. For a main scan field of view L_{MF}=100 microns, an integrated circuit die of 5×5 mm may be inspected without a need to move a stage that holds the workpiece.

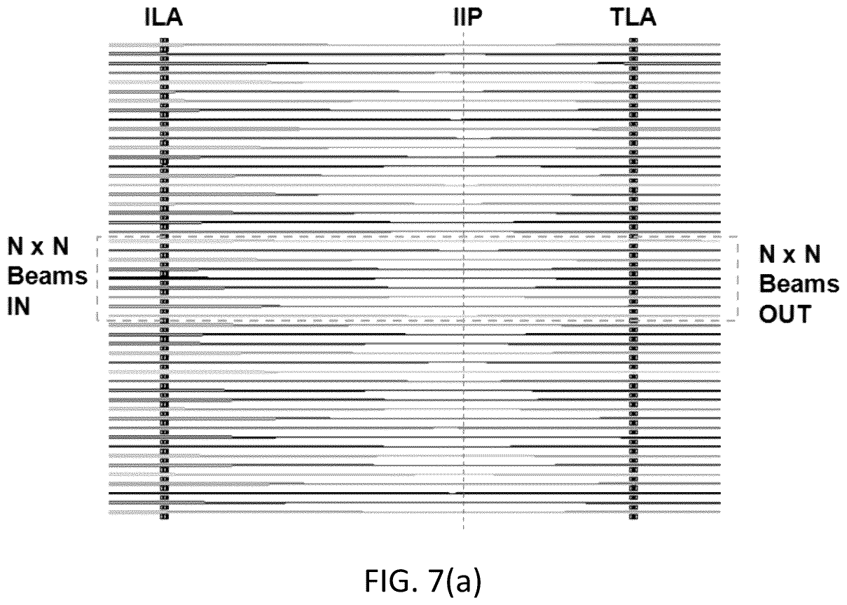

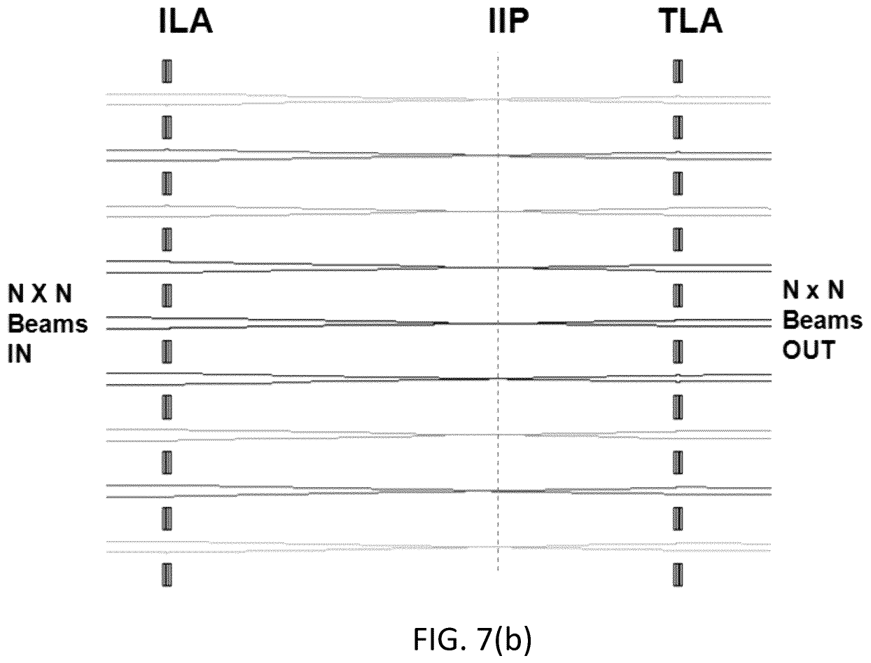

The optical functions of image lens array (ILA) and transfer lens array (TLA) are shown in FIG. 7 with computer simulations. In FIG. 7(a), 50×50 (2500) telecentric electron beamlets enter into the electrostatic fields of the ILA and are focused by the ILA voltage V_{ILA} onto the intermediate image plane (IIP). The sizes of the beamlets are selected by the aperture sizes in the aperture array (AA). The transfer lens array (TLA) focuses these electron beamlets with the voltage V_{ILA} to select optimal NAs (numeric apertures) in the workpiece (image) side for each beamlet such that a minimal spot size (i.e., best resolution) of each beamlet can be achieved. The IIP position may be optimized by varying the V_{ILA} for minimizing the spot size of each beamlet.

FIG. 7(b) shows an enlarged view of the computer-simulated electron trajectories in FIG. 7(a) in the radial direction. It is seen from FIG. 7(b) that all electron beamlets (e.g., 2500 beamlets) may be simultaneously focused at the IIP by a single voltage of V_{ILA} with the same optical properties.

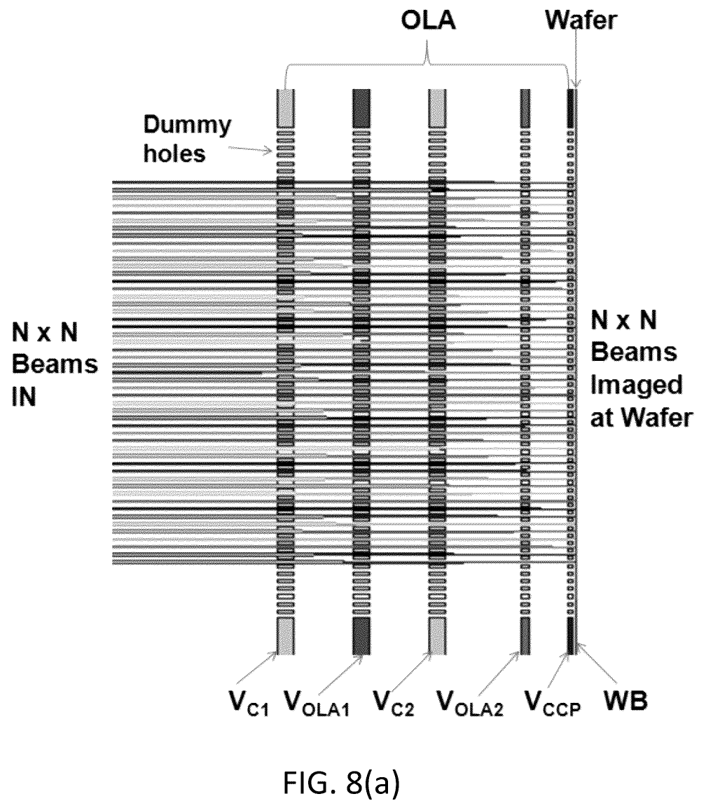

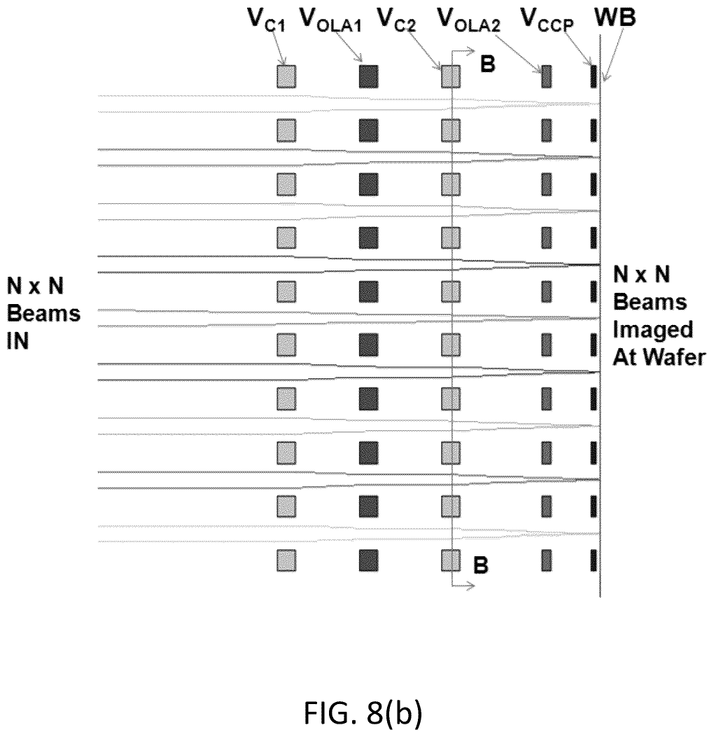

FIG. 8(a) shows the schematic of objective lens array (OLA) and simulation of trajectories with 50×50 electron beamlets. The OLA includes five electrode plates applied with the voltages of V_{C1}, V_{OLA1}, V_{C2}, V_{OLA2}, and V_{CCP}, respectively. The OLA is deployed relatively close to the workpiece. The working distance may be tens of microns for collecting the secondary electron signal as much as possible. The workpiece may be considered as a part of the objective lens fields and it is normally biased with a negative voltage. For example, the wafer bias (WB) can be −4 kV if the beam energy (BE) is 5 kV and landing energy (LE) is 1 keV. The electrode with a voltage of V_{CCP} is referred to as the charge control plate (CCP) for defining the extracting field on the workpiece surface. The working distance is the gap between the CCP and a surface of the workpiece. The voltages of V_{C1} and V_{C2} may be zero (ground). The voltages of V_{OLA1} and V_{OLA2} can be selected to best focus the primary and secondary electron beamlets for optimum primary electron image resolutions and maximum secondary electron collection efficiencies, respectively.

The holes with the OLA electrode plates may be identical (i.e., the same hole diameters) or similar (i.e., with different hole diameters) to those with the ILA and TLA in FIG. 6. However, the electrode gap distances with the OLA can be different than those of the ILA and TLA. These gap distances varying in hundreds of microns to millimeters can be optimized to reduce objective lens aberrations and improve secondary electron collection efficiencies. A number of dummy holes may be designed for maintaining imaging uniformity in a large beamlet FOV (L_{d}×L_{d}) because the gap distances between the electrodes in OLA may be relatively large.

FIG. 8(b) indicates an enlarged view of the FIG. 8(a) in the radial direction, showing that 50×50 primary electron beamlets are computer-simulated and focused (image-formed) at a workpiece simultaneously. The cross-section (e.g. the B-B plane) view in FIG. 8(b) is similar to FIG. 6, but has more holes, including the dummy holes.

Workpiece inspection includes collecting and imaging secondary electrons (SE) with a detector. In a multi-electron beam tool, thousands of electron beamlets emitted from a workpiece can be separately detected without cross-talks between beamlets. The secondary electron collection efficiency is directly related to the tool throughput. Referring to Equation (1), a higher SE collection efficiency allows to use higher scan speed (i.e., the higher frequency f) and reduces the total pixel time.

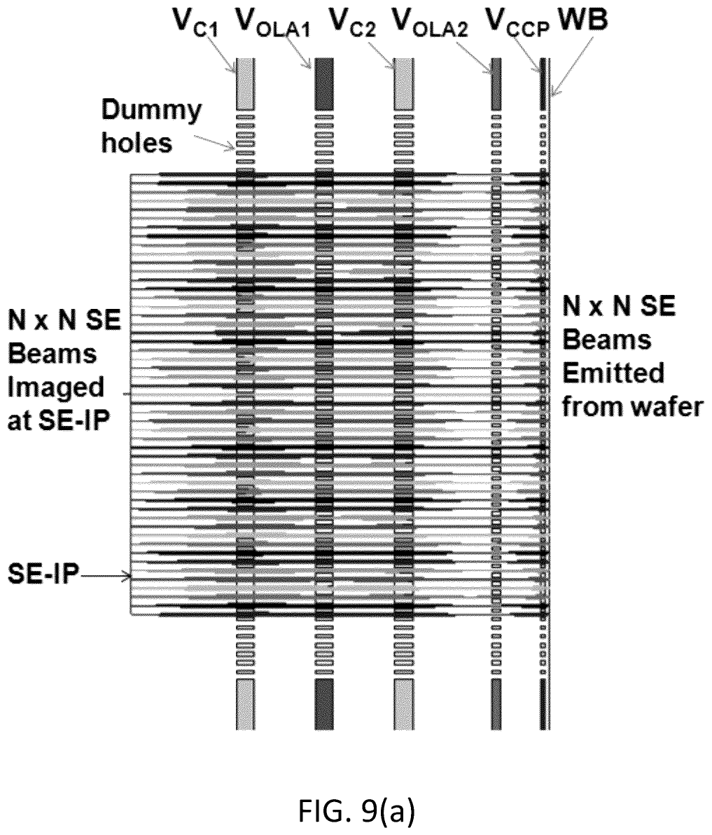

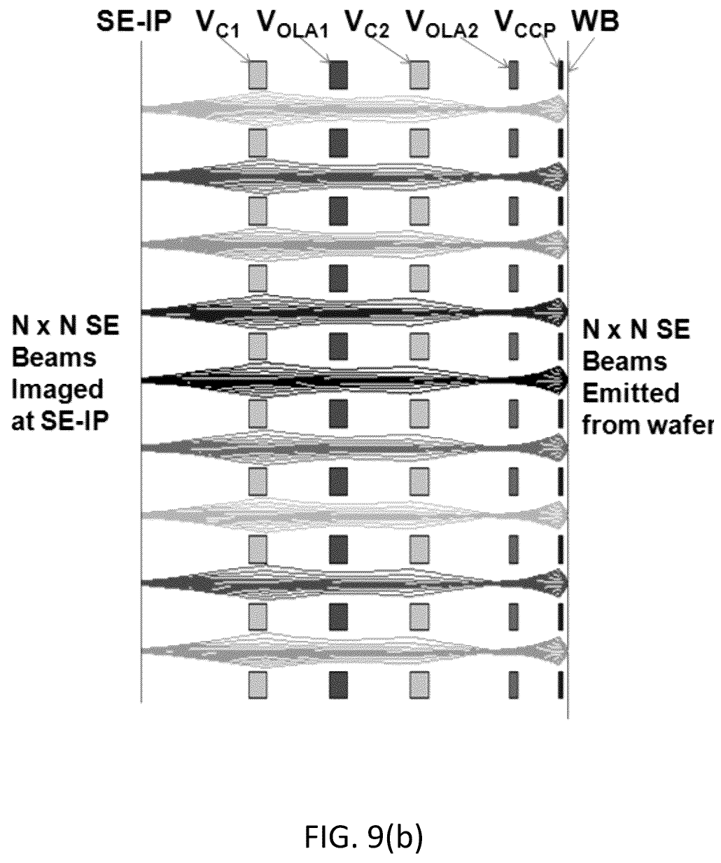

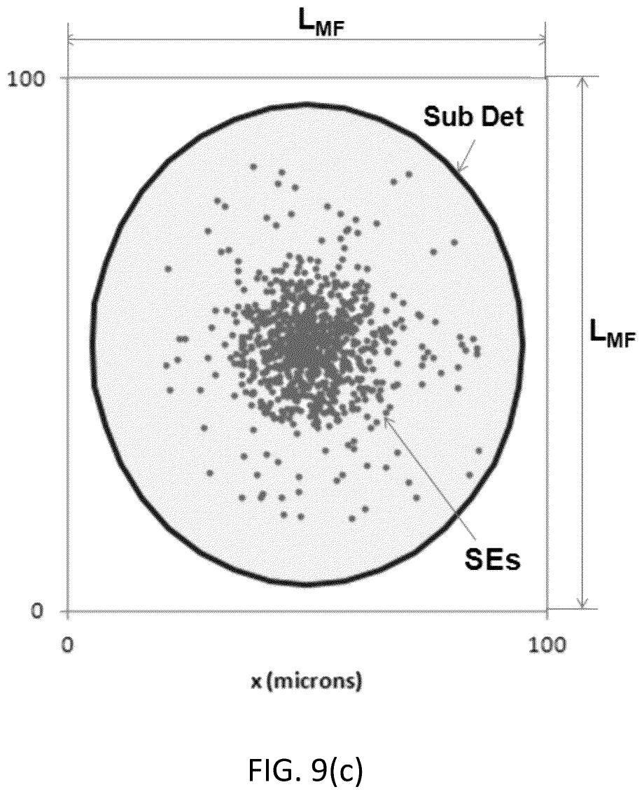

FIG. 9(a) shows ray-tracing simulations of 50×50 secondary electron beamlets emitted from a workpiece. All voltages on the electrode plates (including the workpiece) in the SE beamlet simulations are the same as those in the PE beamlet simulations. FIG. 9(b) shows an enlarged view of the secondary electron trajectories in FIG. 9(a). In the ray-tracing simulations for

FIG. 9(a) and FIG. 9(b), only one SE-energy is used for the simplicity of illustration. To direct the SEs to pass through all electrode holes in tens of microns, two beam crossovers (or images) of each SE beamlet are formed. The first beamlet crossover is around the charge control plate (CCP) hole. The second beamlet crossover is at the SE image plane (SE-IP) that is arranged at a point away from the OLA exit plane (e.g., the V_{C1} electrode plane).

Only spherical aberrations in the two image planes may be seen from FIG. 9(b) because only one SE-energy is used in the ray-tracing simulations. The SE emission has wide energy distributions, so the chromatic aberrations in the two image planes can be determined.

FIG. 9(c) shows secondary electron distributions in the image plane of the OLA (SE-IP) according to Monte Carlo (MC) simulations. In the Monte Carlo simulations, the SE emission energies and emission polar angles are randomly generated according to an SE emission modeling of physics. From this Monte Carlo simulation, more than 80% of SEs from wafer pass through all electrode holes towards to an assumed sub-detector (Sub-Det) at SE-IP. The area of all SE distributions including the chromatic blurs at the SE-IP can be smaller than the size of sub-detector (ø90 microns). The sub-detector can be smaller than the main field (L_{MF}=100 microns) and/or the pitch between beamlets (s=100 microns). All secondary electrons in each beamlet exiting the OLA may be collected by a detector array at the SE-IP. There is no cross-talk between SE beamlets.

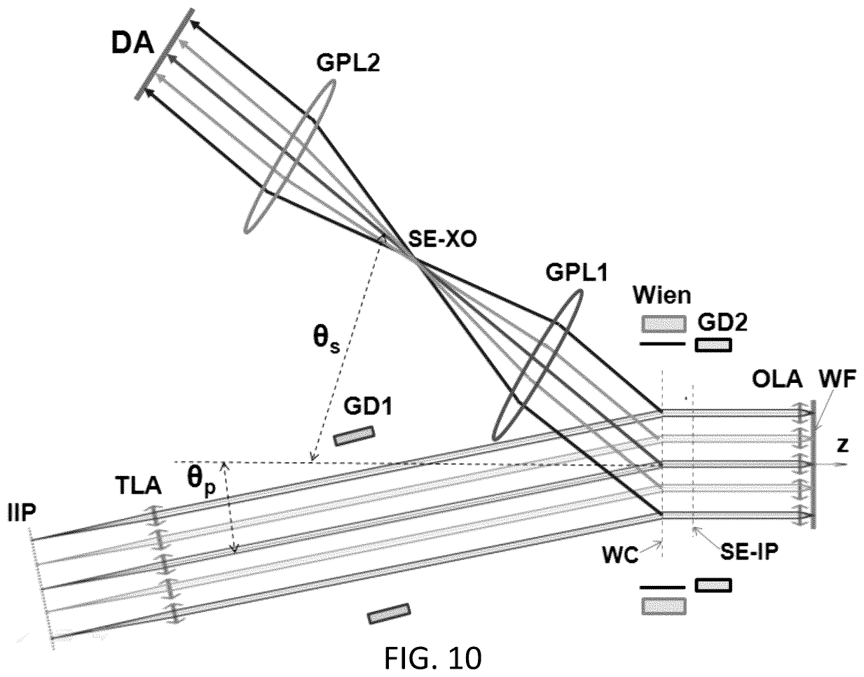

FIG. 10 shows an optics with which the resolutions of primary electron beamlets at the workpiece are improved and the secondary electrons of thousands of beamlets at the final detector array (DA) are efficiently collected without cross-talk.

A Wien filter (Wien) is used to split the secondary electron signals from primary electrons, as shown in FIG. 10. However, the Wien filter introduces transfer chromatic (TC) aberrations due to the energy dispersion from electron sources. The TC blurs can degrade the primary electron beamlet resolutions.

The source energy dispersion blurs can be cancelled with a Wien filter.

In a summary, if the angles θₚ and θₛ in FIG. 10 meet the relation defined in Equation (4) below, the source energy dispersion blurs generated by the electrostatic and magnetic deflection fields in a Wien filter can cancel each other.

$$\frac{{θ}_{P}}{{θ}_{S}} = \frac{1 - ρ}{1 + 2 \sqrt{1 - ρ}} \qquad ( 4 )$$

$$ρ = \frac{LE}{{V}_{P}} = \frac{{V}_{P} - {V}_{S}}{{V}_{P}} = 1 - \frac{{V}_{S}}{{V}_{P}} ( ρ = 0 ∼ 1 ) \qquad ( 5 )$$

In Equations (4) and (5), Vₚ and Vₛ are the energy voltages of the primary electron beams (PEB) and secondary electron beams (SEB) in the Wien filter region, and the LE is the landing energy of the primary electron beams on the wafer. For example, ρ=⅕ if LE=1 k eV and Vₚ=5 kV, giving θₚ/θs=0.29. If the primary beam column tilt is 5 degrees (θₚ=50) with respect to the center of the Wien filter, then the secondary electron column tilt is 17.4 degrees (θₛ=17.4⁰).

Equation (4) meets not only the cancelling condition of source energy dispersion, but also the alignment condition of the primary beam. The tilt primary beam with an angle θₚ in FIG. 10 is aligned to the objective lens (OL) optical axis if the alignment condition is met. For the alignment condition, the electrostatic field of the Wien filter deflects at an angle of θₚ in the y-direction and the magnetic field of the Wien filter deflects at an angle of 2θₚ in the −y-direction. The cross-section of FIG. 10 is in the yoz plane. The Wien filter electrostatic and magnetic deflection fields may be generated by octupoles. Deflection fields with octupoles are fairly uniform in a large central region and the energy dispersion cancellations are fairly uniform in a large region such that the energy dispersion blurs of thousands of beamlets in FIG. 10 may be cancelled by a global Wien filter simultaneously.

In FIG. 10, the secondary electron beamlets are image-formed on the detector array (DA) after they are deflected an angle of θₛ by the Wien filter. Two global projection lenses, GPL1 and GPL2, are used in the projection optics. The object and image planes of the projection optics are the SE-IP and DA in FIG. 10, respectively. The SE-IP is the secondary electron image plane in the OLA exit side, as can be seen in FIG. 9.

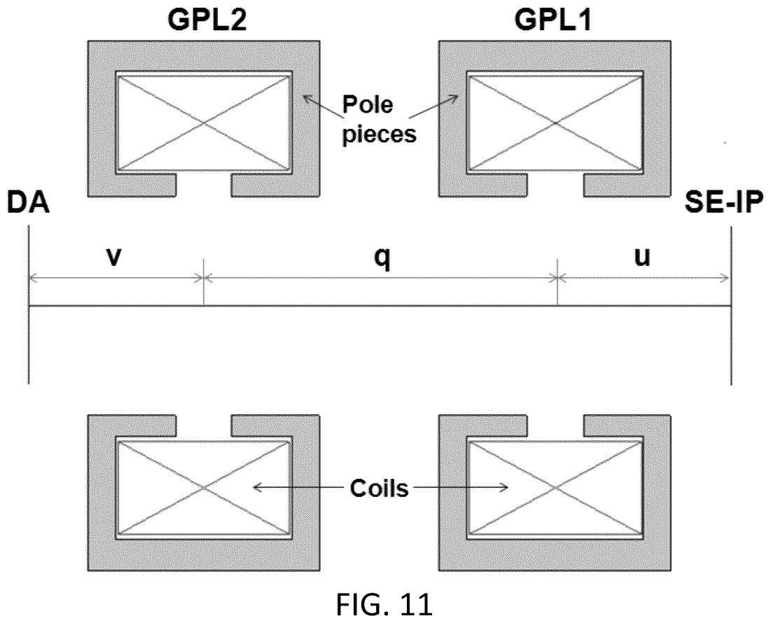

The two global projection lenses GPL1 and GPL2 may be magnetic lenses with relatively large inner diameters, as shown in FIG. 11. To image-form a large object in the SE-IP (e.g. 5×5 mm in FIG. 9), the projection optics in FIG. 11 are configured to cancel the SE beamlet rotation, coma/transfer chromatic (TC) blurs, and distortion. The projection optics in FIG. 11 also are configured to minimize the field curvature/astigmatism blurs. These requirements may be implemented by designing the GPL1 magnetic field to be identical to GPL2 magnetic field (e.g. the equal pole piece gap and inner diameter), but with opposite directions (polarity) of the excitation coil currents. To keep a 1:1 imaging relation from SE-IP to DA when the optical magnification equals 1x, the projection optics is kept to be v=u and q=2u, in which u is the object distance of PGL1, v is the image distance of GPL2, and q is the distance between GPL1 and GPL2 (q=2u).

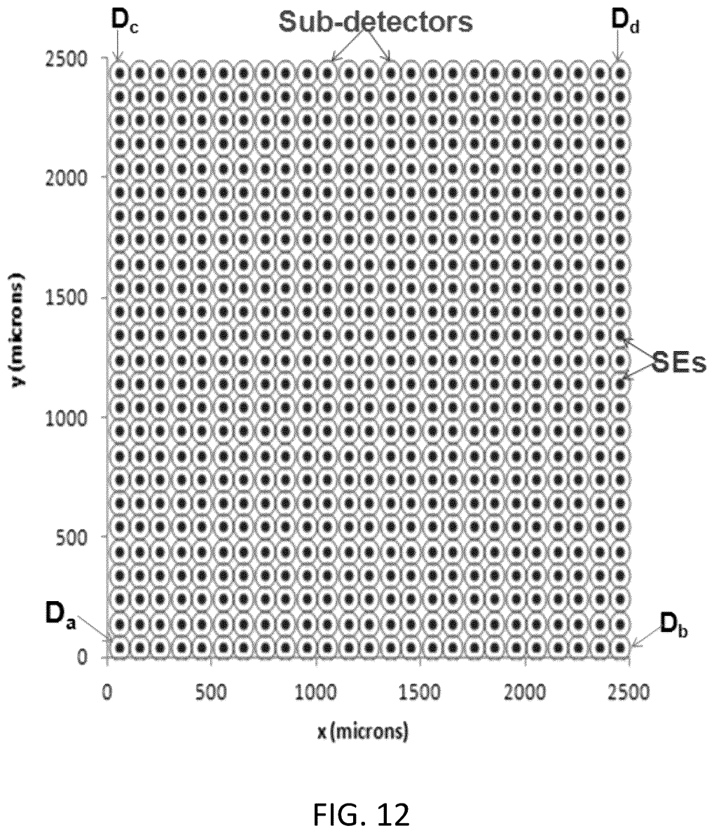

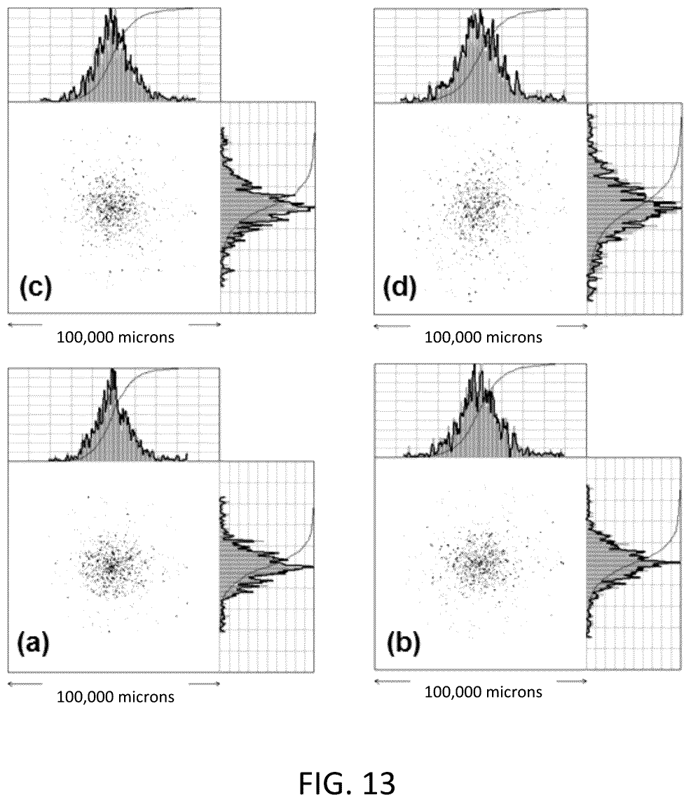

The computer simulation with Monte Carlo method shows the performance of the SE projection optics shown in FIGS. 10-11. In general, the detector array (DA) detects all the SE beamlet signals with high collection efficiencies and without cross-talk between SE beamlets, as can be seen in FIGS. 12-13.

Based on FIG. 4 and FIG. 10, the system can include a stage configured to hold a workpiece (e.g., wafer (WF)). There may be a single global magnetic lens in a path of the electron beam, such as global gun lens (GGL). A global beam-limiting aperture (GBLA) is in the path of the electron beam downstream of the global gun lens (GGL). A single global collimated lens (GCL) is in the path of the electron beam downstream of the global beam-limiting aperture. The single global collimated lens (GCL) is configured to focus the electron beam. An aperture array (AA) is in the path of the electron beam downstream of the single global collimated lens (GCL). The aperture array (AA) is configured to generate a plurality of beamlets from the electron beam. For example, the aperture array (AA) may generate at least 1000 beamlets or at least 2500 beamlets. The aperture array (AA) can be illuminated telecentrically by the electron beam.

Regarding the optical components, a global component can refer to only having one component for the entire electron beam or for all the beamlets.

The electron beam can be generated by an electron beam source, such as a thermal field emission source. The thermal field emission source may be the only source for the electron beam.

An image lens array (ILA) is in a path of the beamlets downstream of the aperture array. The beamlets can be individually focused by the image lens array onto the intermediate image plane. A transfer lens array (TLA) is in the path of the beamlets downstream of the image lens array (ILA). Spacing of apertures in the image lens array (ILA) and transfer lens array (TLA) may be from 10 μm to 1 mm.

The beamlets are directed at the workpiece on the stage using the transfer lens array (TLA). The beamlets may be configured to illuminate a single die on the workpiece. The path of the beamlets does not include a crossover. Thus, each of the beamlets may be directed at the wafer WF without crossing another of the beamlets. The beamlets can be directed toward the wafer WF with a cross-section that is an array. This array may be relatively constant as the beamlets get closer to the wafer WF.

In an instance, the image lens array (ILA) includes three electrode plates. Each of the electrode plates includes a plurality of apertures. One of the electrode plates is biased such that the beamlets are focused. Another two of the electrode plates are grounded.

The system can include a Wien filter (Wien) in the path of the beamlets between the transfer lens array (TLA) and the stage. The Wien filter is configured to split secondary electrons from primary electrons. A detector array (DA) can be configured to measure the secondary electrons. A relationship between an angle of the beamlets relative to the workpiece and an angle caused by deflection using the Wien filter is such that source energy dispersion blurs generated by the electrostatic and magnetic deflection fields in the Wien filter are cancelled. The detector array (DA) and a global projection lens (GPL1 or GPL2) are configured to be mechanically adjusted along the optical axis, which can be along a path of the beamlets.

In an instance, the system includes a pre-scanner (GD1) and a main scanner (GD2). The pre-scanner and the main-scanner are configured to scan the beamlets simultaneously.

The system may include an objective lens array (OLA) disposed less than 100 μm from a surface of the workpiece along an optical path. The objective lens array (OLA) can define a gap distance between electrodes in the objective lens array (OLA) configured to optimize image resolutions of primary electron beamlets and collection efficiencies of secondary electron beamlets.

FIG. 12 shows the first quadrant detector array (DA) with 25×25 (i.e., 625) sub-detectors. The size of a sub-detector can be 100 microns, which may be equal to a main field size L_{MF}=100 microns or the pitch between beamlets s=100 microns. Because the distortions are cancelled with the projection optics in FIG. 11, the SEs with each beamlet are collected/distributed in the centers of the sub-detectors.

FIG. 13(a)-(d) show the Monte Carlo simulations of SE collections by the sub-detectors Dₐ, D_{b}, D_{c}, and D_{d} in FIG. 12, respectively. The SE detection simulation uses the secondary electrons at SE-IP in FIG. 9(c) as initial conditions (i.e., initial positions and directions), being equivalent to collect the SEs from wafer to DA. FIG. 13 shows high collection efficiencies for all beams and without signal cross-talk between beams for the SE signal collection with each beamlet. In the global projection optics, the SE beamlet crossover (SE-xo) between GPL1 and GPL2 in FIG. 10 does not influence the SE beamlet spot size at the DA even if the Coulomb interactions between electrons are taken into account because the SE spot size at the DA is approximately tens of microns instead of approximately tens of nanometers at the workpiece in PE beamlets.

The de-scan deflectors are not shown in the SE projection optics in FIG. 10 and FIG. 11. These can be used to avoid the cross-talks between the beamlets in FIG. 12.

The SE-IP position in FIG. 9 may be varied along the optical axis with the changes of optical conditions (e.g., the changes of landing energy (LE) or beam energy (BE), etc.). Thus, the object distance of the global projection lens GPL1(u) in FIG. 11 may be varied. To maintain a 1:1 optical magnification and cancel the SE beamlet rotation, distortion, and coma from the SE-IP to DA, the global projection lens GPL2 and detector array (DA) positions may be mechanically adjustable along the optical axis to maintain the relations v=u and q=2u in FIG. 11.

Compared to the wafer inspection with a single electron beam (SEB), the multi-electron beam (MEB) method increases the throughput by more than a hundred times to thousands of times depending on how many scan sub-fields are divided from a scan main field. For example, if the sub-field is equal to the main field (100 microns), the MEB throughput is raised more than 11000×. If the main field is divided into nine sub-fields, the MEB throughput is raised 347× assuming the SEB is scanning over a 100 μm main field.

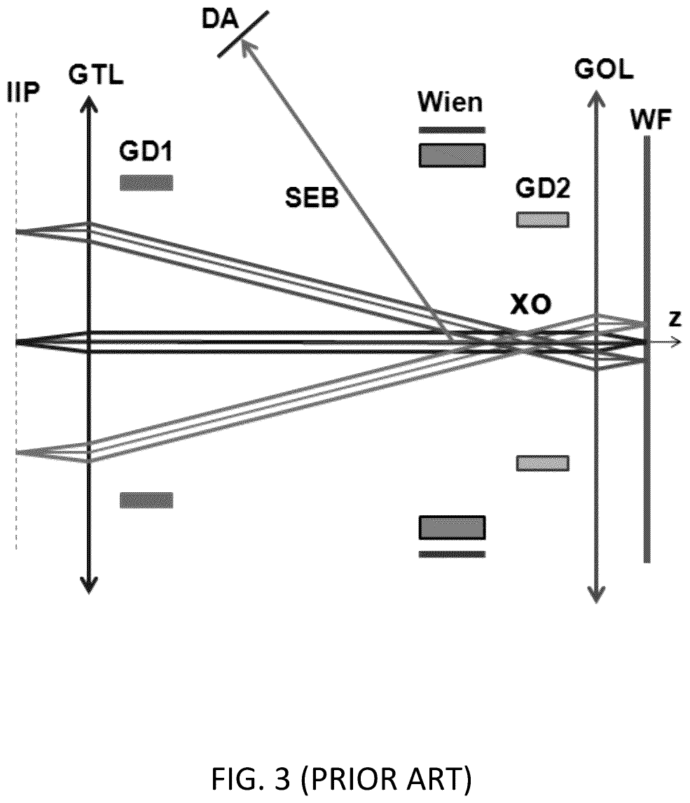

Previously, all beamlets (all beam currents) intersect around the beam crossover (x0, referring to FIG. 3). The Coulomb interactions between electrons around the crossover become dominant in degrading each individual resolution of beamlets at the workpiece. Accordingly, a beam crossover in the projection optics may either strongly limit the beamlet number (given a constant beamlet current) or each beamlet current (given a constant beamlet number). An arrangement of parallel beamlets removes the beam crossover or the Coulomb interactions between beamlet electrons, improving each beamlet resolution.

In an embodiment, the electron emissions in FIG. 4 may be implemented with a thermal field emission (TFE) source, a cathode ray tube (CRT) source, or a photocathode source. The TFE source provides a high brightness emission, but the emission uniformity over the emission angle α in FIG. 4 may be limited. The CRT source provides relatively low brightness of emission, but has wider emission uniformity than the TFE source. Patterned electron sourcelets with photocathode emissions also can be used.

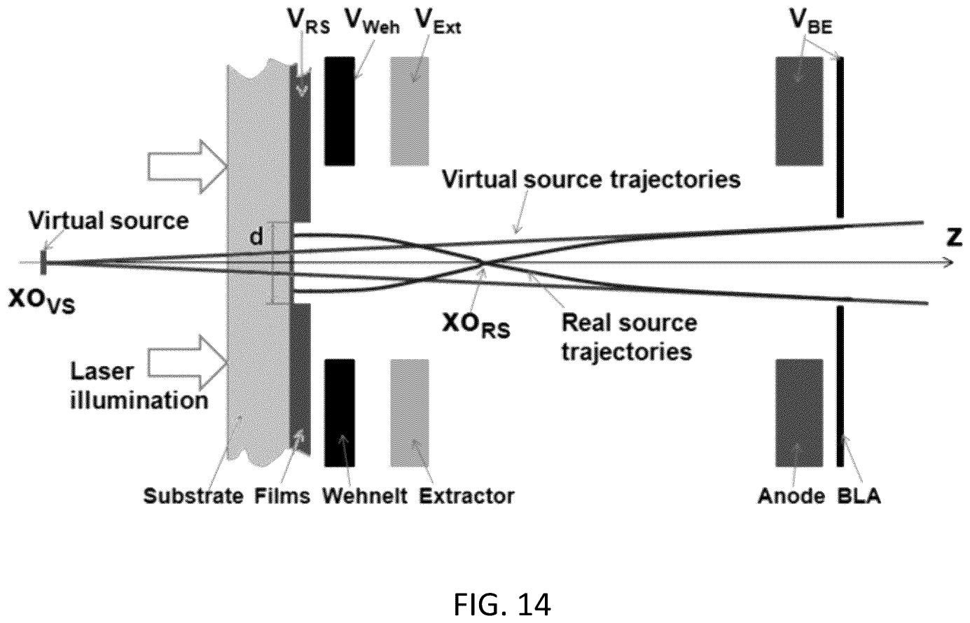

Based on a photoelectric effect, FIG. 14 shows the method of creating electron emission with a patterned photocathode. The photocathode thin-films are deposited on a transparent substrate (e.g. sapphire) under the illumination of a laser beam.

A gold material may be selected as the photoemitter because of its stability and well-characterized photoemission properties. The quantum-efficiency of the gold film under back laser-illumination may be dependent on the thickness of the film. A thickness (e.g., from 10 nm to 20 nm) of the gold film can provide the highest quantum-efficiency. The quantum-efficiency becomes several orders of magnitude lower if the gold film is, for example, greater than 5× thicker than the optimal thickness. Accordingly, the film in FIG. 14 is created with step-layers. The thinner film region with an optimal thickness and diameter is defined and used as the photocathode emission area, from which the electrons, referring to the real source trajectories in FIG. 14, are emitted and accelerated. The thicker film region is defined and used as the shields of blocking the electron emissions because of negligible quantum-efficiencies.

The gun electron optics includes the electrodes of the photocathode film, Wehnelt, extractor, and anode applied with the voltages (with respect to the beam energy) of V_{RS}, V_{Weh}, V_{Ext}, and V_{BE}, respectively. The anode may be grounded. The real voltages with respect to the ground are V_{RS}−V_{BE}, V_{Weh}−V_{BE}, V_{Ext}−V_{BE}, and zero, respectively.

The Wehnelt electrode can be used to control the beam shape of the electrons after emission from the photocathode. The extractor electrode can be used to direct the electron beam into the acceleration region between the extractor and anode. The anode can be used to accelerate the electron beam to the required beam energy (BE). A beam limiting aperture (BLA) with a bore size smaller than the anode bore can be positioned after the anode to select the central portion of the electron beam to control the geometric aberration blurs.

The real source in FIG. 14 may be modeled with a virtual source behind the substrate. In the modeling, the real beam crossover (XO_{RS}) created with the electrons from the photocathode is image-formed as XO_{VS} through the anode lens (acceleration lens). Thus, the XO_{RS} is the object of the XO_{VS}, and the XO_{VS} is in the image-side of the anode lens with the same potential of the anode V_{BE} with respect to beam energy. The virtual source trajectories can be the straight lines, which may be the tangential lines of the real source trajectories in the BLA exit plane.

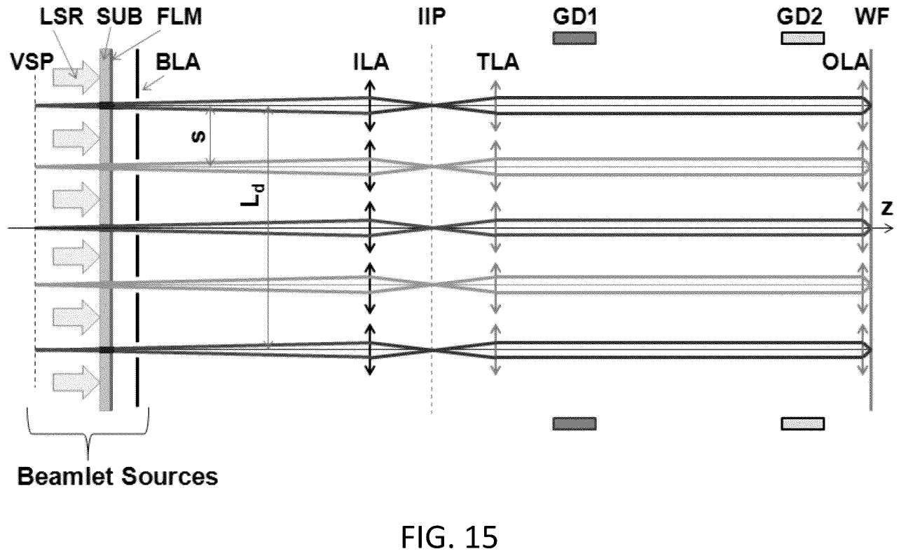

FIG. 15 shows a complete multi-electron beam optics with photocathode emission sourcelets. The module of beamlet sources is used to replace the optical column from tip to aperture array (AA) in FIG. 4. The patterned thin films (FLM) on the transparent substrate (SUB) are illuminated by the laser beam (LSR), and the independent electron beamlets are emitted from the virtual source plane (VSP). The single beam current is limited by the beam-limiting aperture (BLA) and controlled by the strength of the illuminating laser beam. The spacing of the patterned photocathode sourcelets may be s, being equal to the pitch between electron beamlets in the complete optical column in FIG. 15. The size of the patterned photocathode sourcelets may be L_{d}×L_{d} being equal to the size of an integrated circuit die during inspection.

Thus, a transparent substrate is in the path of the beamlets in an embodiment. The transparent substrate has a patterned thin film. A plurality of laser beams illuminate the patterned thin film.

The throughput of a wafer inspection tool with thousands of electron beams (keBs) may be highest if the pitch between beamlets is equal to the size of main field (i.e., s=LMF in FIG. 4) and if the raster scan covers a complete main field without stage motions. If the main field is designed too large, the scan-deflection blurs may hurt resolution and image uniformity. If the main field (the pitch between beamlets) is designed too small, the axial resolution may be degraded by the spherical aberration because of reduced sizes of the holes with the micro lenses in ILA, TLA, and OLA.

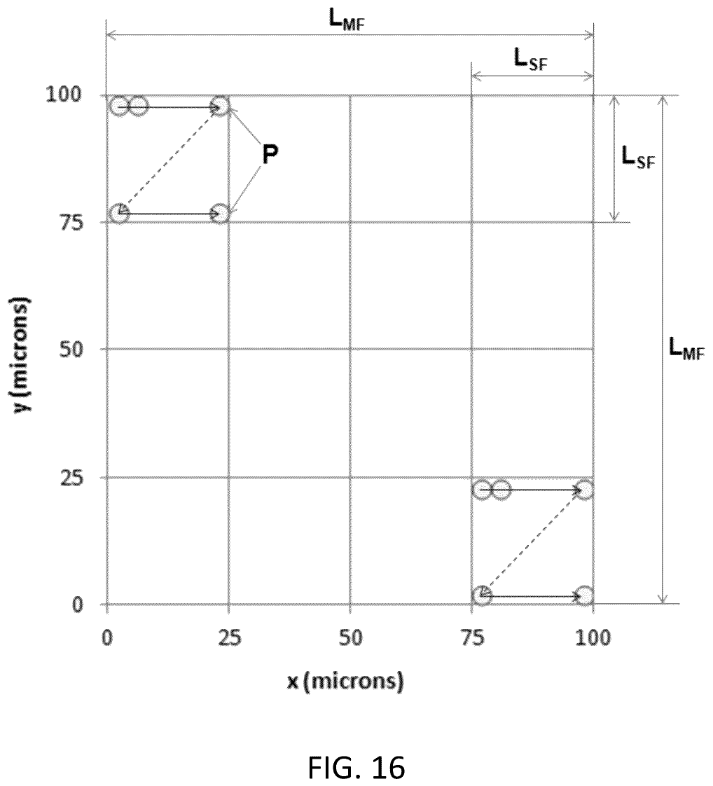

FIG. 16 shows a scheme of step-and-scan in a main field (LMF×LMF). The main field size is still equal to the spacing between beamlets (i.e., s=LMF). The main field is further divided into certain sub-fields (e.g., LSF=25 microns and LMF=100 microns). The stage is moved to the center of the first sub-field (e.g., x=12.5 microns and y=87.5 microns) and the electron beamlet performs the raster scan in the first sub-field. Then the stage is moved to the second sub-field for the raster scan repeatedly until the last sub-field (e.g., x=87.5 microns and y=12.5 microns) is raster-scanned.

With the step-and-scan scheme in a main field, the throughput of the multi-electron beam system in FIG. 4, FIG. 10, or FIG. 15 may be determined. This includes the conditions of pixel size P=15 nm, scan frequency f=400 MHZ, single stage motion time t_{stg}=0.4 seconds, single retrace time tᵣₜᵣ=1 micro second, and a size of an integrated circuit die of 5000×5000 square microns (L_{d}=5000 microns), within which 50×50 (2500) electron beamlets are deployed with the beamlet pitch of s=100 microns. The main field (L_{MF}=100 microns) of each beamlet is divided into 4×4 sub-fields in FIG. 16. Each beamlet separately raster-scans over a sub-field of LSF=25 microns. Accordingly, the total pixel time Tₚᵢₓ, total retrace time Tᵣₜᵣ, and total stage motion time T_{stg} are 0.11 seconds, 0.03 seconds, and 6.4 seconds, respectively. This gives the total time Ttₒₜ=Tₚᵢₓ+Tᵣₜᵣ+T_{stg}=6.81 seconds. Compared to the total time of 21.6 minutes used for inspecting a die in the size of 5000×5000 square microns with a single electron beam, the multi-electron beam scheme increases the throughput 190× even if still assuming the single electron beam to scan over a main field of 100 microns (i.e., no stage motions within a 100 micron MF). Thus, if the MF of 100 microns is divided into 3×3 sub-fields or 2×2 sub-fields, the multi-electron beam scheme increases the throughput 347× or 758× under the same conditions, respectively.

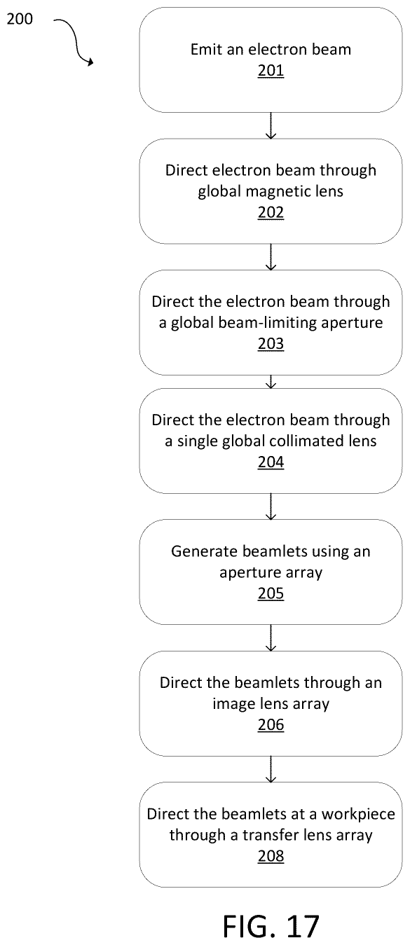

FIG. 17 shows a flowchart of a method 200. An electron beam is emitted from a thermal field emission source or another electron source at 201. The electron beam is directed through a single global magnetic lens at 202. The electron beam is then directed through a global beam-limiting aperture downstream of the single global magnetic lens at 203 and a single global collimated lens in the path of the electron beam downstream of the global beam-limiting aperture at 204. The electron beam is focused by the single global collimated lens.

A plurality of beamlets are generated from the electron beam at 205 using an aperture array downstream of the single global collimated lens. The plurality of beamlets can include at least 1000 beamlets or at least 2500 beamlets. The aperture array can be illuminated telecentrically by the electron beam.

The beamlets are directed through an image lens array in a path of the beamlets downstream of the aperture array at 206. This individually focuses the beamlets onto the intermediate image plane with the image lens array. Then the beamlets are directed at a workpiece on a stage at 208 using a transfer lens array downstream of the image lens array. The beamlets may illuminate a single die on the workpiece.

In an embodiment, secondary electrons are split from primary electrons between the transfer lens and the stage using a Wien filter. The secondary electrons can then be measured. Energy dispersion blurs generated by the electrostatic and magnetic deflection fields in the Wien filter can be cancelled using a relationship between an angle of the beamlets relative to the workpiece and an angle caused by deflection using the Wien filter. Transfer chromatic blur induced by the Wien filter due to source energy spread can be corrected by cancelling the source energy spread. A position of a detector array and a global projection lens can be adjusted along an optical axis, which may be a path of the secondary electrons.

In an embodiment, the beamlets are simultaneously scanned with a pre-scanner and a main scanner.

In an embodiment, a path of the beamlets does not include a crossover.

In an embodiment, each of the beamlets is formed and imaged separately using an image lens array, a transfer lens array and an objective lens array.

In an embodiment, a same focusing voltage is applied to an image lens array, a transfer lens array and an objective lens array that the beamlets pass through.

In an embodiment, the method 200 includes image-formation of secondary electron beamlets from a secondary electron image plane to a detector array through a projection optics. The projection optics includes two global project lenses thereby cancelling secondary electron beamlet rotation, coma, distortion, and transfer chromatic aberration.

In an embodiment, the method 200 includes creating at least 1000 beamlets modulated by a laser using patterned photocathode sourcelets on an image lens array, a transfer lens array and an objective lens array.

In an instance, the electron beam or beamlets may be directed between these components in a direct manner. Thus, there may not be other optical components between the components described herein. In another instance, additional optical components are located between the components described herein.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
an electron source that emits an electron beam;
a stage configured to hold a workpiece;
a single global magnetic lens in a path of the electron beam;
a global beam-limiting aperture in the path of the electron beam downstream of the single global magnetic lens;
a single global collimated lens in the path of the electron beam downstream of the global beam-limiting aperture, wherein the single global collimated lens is configured to focus the electron beam;
an aperture array in the path of the electron beam downstream of the single global collimated lens, wherein the aperture array is configured to generate a plurality of beamlets from the electron beam, wherein the aperture array is illuminated telecentrically by the electron beam, and wherein the plurality of beamlets includes at least 1000 of the beamlets;
an image lens array in a path of the beamlets downstream of the aperture array, wherein the beamlets are individually focused by the image lens array onto the intermediate image plane; and
a transfer lens array in the path of the beamlets downstream of the image lens array, wherein the beamlets are directed at the workpiece on the stage using the transfer lens array, wherein the path of the beamlets does not include a crossover.

2. The system of claim 1, wherein the beamlets include at least 2500 of the beamlets.

3. The system of claim 1, wherein the beamlets are configured to illuminate a single die on the workpiece.

4. The system of claim 1, wherein the image lens array includes three electrode plates, wherein each of the electrode plates includes a plurality of apertures, wherein one of the electrode plates is biased such that the beamlets are focused, and wherein another two of the electrode plates are grounded.

5. The system of claim 1, further comprising:
a Wien filter disposed in the path of the beamlets between the transfer lens array and the stage, wherein the Wien filter is configured to split secondary electrons from primary electrons; and
a detector array configured to measure the secondary electrons.

6. The system of claim 5, wherein a relationship between an angle of the beamlets relative to the workpiece and an angle caused by deflection using the Wien filter is such that source energy dispersion blurs generated by the electrostatic and magnetic deflection fields in the Wien filter are cancelled.

7. The system of claim 5, wherein the detector array and a global projection lens in a path of the second electrons are configured to be mechanically adjusted along the optical axis.

8. The system of claim 1, wherein spacing of apertures in the image lens array and transfer lens array is from 10 μm to 1 mm.

9. The system of claim 1, further comprising a pre-scanner and a main scanner in the path of the beamlets, wherein the pre-scanner and the main-scanner are configured to scan the beamlets simultaneously.

10. The system of claim 1, wherein the electron source is a thermal field emission source, and wherein the thermal field emission source is the only source for the electron beam.

11. The system of claim 1, wherein the electron source includes:
a transparent substrate in the path of the beamlets, wherein the transparent substrate has a patterned thin film; and
a plurality of laser beams that illuminate the patterned thin film.

12. The system of claim 1, further comprising an objective lens array that defines a gap distance between electrodes in the objective lens array configured to optimize image resolutions of primary electron beamlets and collection efficiencies of secondary electron beamlets.

13. The system of claim 1, further comprising an objective lens array disposed less than 100 μm along the optical path of the beamlets from a surface of the workpiece.

14. A method comprising:
emitting an electron beam with an electron source;
directing the electron beam through a single global magnetic lens;
directing the electron beam through a global beam-limiting aperture downstream of the single global magnetic lens;
directing the electron beam through a single global collimated lens in the path of the electron beam downstream of the global beam-limiting aperture whereby the electron beam is focused by the single global collimated lens;
generating a plurality of beamlets from the electron beam using an aperture array downstream of the single global collimated lens, wherein the plurality of beamlets includes at least 1000 of the beamlets, and wherein the aperture array is illuminated telecentrically by the electron beam;
directing the beamlets through an image lens array in a path of the beamlets downstream of the aperture array thereby individually focusing the beamlets onto the intermediate image plane with the image lens array; and
directing the beamlets at a workpiece on a stage using a transfer lens array downstream of the image lens array, wherein a path of the beamlets does not include a crossover.

15. The method of claim 14, wherein the beamlets include at least 2500 of the beamlets.

16. The method of claim 14, wherein the beamlets illuminate a single die on the workpiece.

17. The method of claim 14, further comprising:
splitting secondary electrons from primary electrons between the transfer lens and the stage using a Wien filter; and
measuring the secondary electrons.

18. The method of claim 17, further comprising cancelling energy dispersion blurs generated by the electrostatic and magnetic deflection fields in the Wien filter using a relationship between an angle of the beamlets relative to the workpiece and an angle caused by deflection using the Wien filter.

19. The method of claim 17, further comprising correcting transfer chromatic blur induced by the Wien filter due to source energy spread by cancelling the source energy spread.

20. The method of claim 17, adjusting a position of a detector array and a global projection lens along an optical axis of the secondary electrons.

21. The method of claim 14, further comprising simultaneously scanning the beamlets with a pre-scanner and a main scanner.

22. The method of claim 14, wherein each of the beamlets is formed and imaged separately using an image lens array, a transfer lens array, and an objective lens array.

23. The method of claim 14, wherein a same focusing voltage is applied to an image lens array, a transfer lens array, and an objective lens array that the beamlets pass through.

24. The method of claim 14, further comprising image-formation of secondary electron beamlets from a secondary electron image plane to a detector array through a projection optics, wherein the projection optics includes two global project lenses thereby cancelling secondary electron beamlet rotation, coma, distortion, and transfer chromatic aberration.

25. The method of claim 14, further comprising creating the at least 1000 beamlets modulated by a laser using patterned photocathode sourcelets on an image lens array, a transfer lens array, and an objective lens array.
